(19) United States
(12) Patent Application Publication
(10) Pub. No.: US 2015/0136466 A1
(43) Pub. Date: May 21, 2015

(54) PRINTED CIRCUIT BOARD AND METHOD FOR MANUFACTURING THE SAME

(71) Applicant: SAMSUNG ELECTRO-MECHANICS CO., LTD., Suwon-Si (KR)

(72) Inventor: Jung Youn PANG, Suwon-Si (KR)

(73) Assignee: SAMSUNG ELECTRO-MECHANICS CO., LTD., Suwon-Si (KR)

(21) Appl. No.: 14/275,707

(22) Filed: May 12, 2014

(30) Foreign Application Priority Data
Nov. 19, 2013 (KR) 10-2013-0140716

(51) Int. Cl. H05K 1/02; H05K 3/00; H05K 1/03; G03F 7/30; H05K 1/11

(52) U.S. Cl. CPC H05K 1/0271; G03F 7/30; H05K 1/111; H05K 1/0313; H05K 3/007; H05K 2201/0154; H05K 2201/0145; H05K 2201/0209; H05K 2201/10234
USPC 174/261; 430/325; 427/98.2

(57) ABSTRACT

Disclosed herein are a printed circuit board and a method for manufacturing the same. According to a preferred embodiment of the present invention, the printed circuit board includes: an insulating layer having a connection pad; and a resist layer formed on the insulating layer and provided with an opening so that the connection pad is exposed, wherein a wall surface of an opening of the resist layer may have at least one protrusion.

### CROSS REFERENCE TO RELATED APPLICATION

This application claims the benefit of Korean Patent Application No. 10-2013-0140716, filed on Nov. 19, 2013, entitled “Printed Circuit Board And Method For Manufacturing The Same”, which is hereby incorporated by reference in its entirety into this application.

### BACKGROUND OF THE INVENTION

1. Technical Field

The present invention relates to a printed circuit board and a method for manufacturing the same.

2. Description of the Related Art

For implementing a small, multi-functional electronic device, a printed circuit board (PCB) having high reliability and completeness is required. To this end, research into a technology relating to a surface treatment method of bonding a solder to a substrate is required.

A solder resist applied to protect a conductive circuit of the substrate is provided with an opening by an exposing and developing process, in which the opening shape of the solder resist generally protrudes downward. In this case, the surface treatment layer is formed to protect the conductive circuit exposed by opening the solder resist.

The surface treatment layer is coupled with tin (Sn), and the like within the solder at the time of the solder bonding to form an inter metallic compound (IMC) layer. The IMC layer formed at the time of the solder bonding may be highly likely to be provided with cracks due to a physical impact to a bonded layer between hetero metals.

In a pad structure which protrudes downward, a stress is concentrated on the lower portion of the solder resist when the solder bonding reliability is tested, in which as the IMC layer approaches the stress concentration point, the cracks may occur at a low stress.

### PRIOR ART DOCUMENT

[Patent Document]

(Patent Document 1) International Patent Publication No. WO2007/004658

### SUMMARY OF THE INVENTION

The present invention has been made in an effort to provide a printed circuit board and a method for manufacturing the same capable of changing an opening shape of a solder resist so as to increase bonding characteristics between a substrate and a solder.

According to a preferred embodiment of the present invention, there is provided a printed circuit board, including: an insulating layer having a connection pad; and a resist layer formed on the insulating layer and provided with an opening so that the connection pad is exposed, wherein a wall surface of an opening of the resist layer may have at least one protrusion.

A cross section shape of the opening of the resist layer may have an hourglass shape which the opening is converged at the protrusion between an upper surface and a lower surface of the resist layer.

The opening may include a first portion which is tapered toward the protrusion and the lower surface and a second portion which is tapered toward the protrusion and the upper surface.

The printed circuit board may further include: a solder ball attached on the connection pad.

The printed circuit board may further include: a surface treatment layer between the connection pad and the solder ball.

According to another preferred embodiment of the present invention, there is provided a method for manufacturing a printed circuit board, including: preparing an insulating layer having a connection pad; and forming a resist layer having on opening on the insulating layer so that the connection pad is exposed, wherein a wall surface of the opening of the resist layer may have at least one protrusion.

A cross section shape of the opening of the resist layer may have an hourglass shape which the opening is converged at the protrusion between an upper surface and a lower surface of the resist layer.

The opening may include a first portion which is tapered toward the protrusion and the lower surface and a second portion which is tapered toward the protrusion and the upper surface.

The first portion may be formed by exposing and developing.

The second portion may be formed by laser machining.

The method for manufacturing a printed circuit board may further include: forming a solder ball attached on the connection pad.

The method for manufacturing a printed circuit board may further include: forming a surface treatment layer on the connection pad.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view schematically illustrating a printed circuit board according to a preferred embodiment of the present invention; and

FIGS. 2 to 7 are process cross-sectional views sequentially illustrating a method for manufacturing a printed circuit board according to a preferred embodiment of the present invention.

### DESCRIPTION OF THE PREFERRED EMBODIMENTS

The objects, features, and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side”, and the like, are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Printed Circuit Board

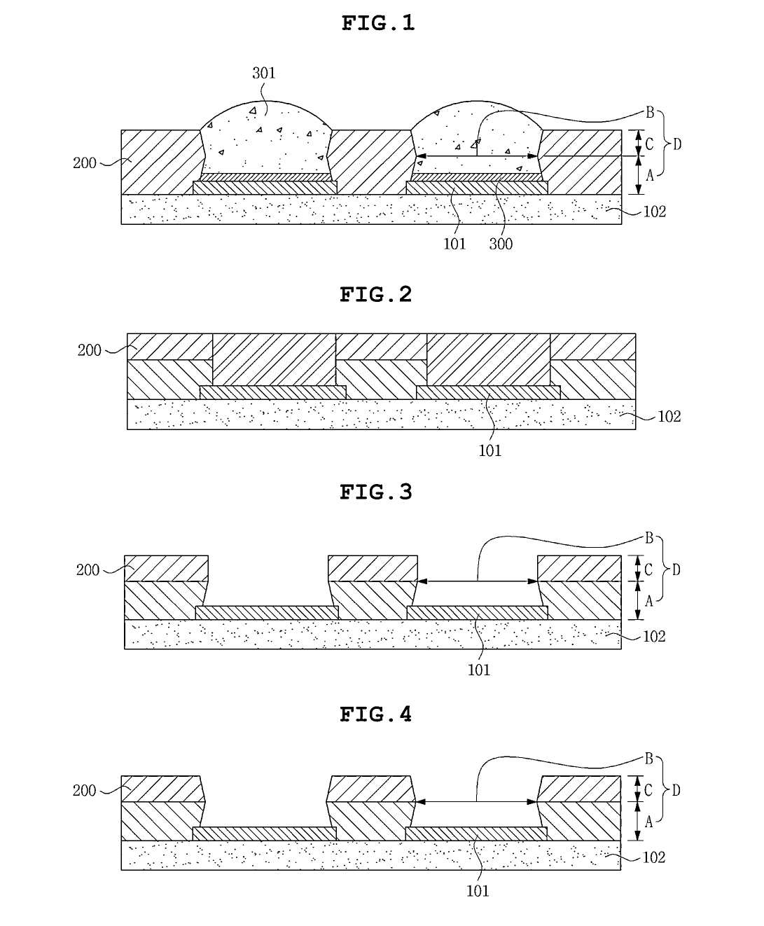

FIG. 1 is a cross-sectional view schematically illustrating a printed circuit board according to a preferred embodiment of the present invention.

Referring to FIG. 1, a printed circuit board 100 according to the preferred embodiment of the present invention includes an insulating layer 102 having a connection pad 101 and a resist layer 200 which is formed on the insulating layer 102 and is provided with an opening D to expose a connection pad 101. In this case, a wall surface of the opening D of the resist layer 200 has at least one protrusion B.

The printed circuit board 100 may be formed of a basic member having a film shape including a resin material and materials, which is called a copper clad lamination (CCL), having patterns formed on both surfaces thereof and as the resin material which is a basic member, a thermosetting resin such as an epoxy resin, a thermoplastic resin such as polyimide, polyethylene terephthalate (PET), and a resin, for example, a prepreg, in which reinforcing materials, such as a glass fiber and an inorganic filler, are impregnated therein may be used. Further, the thermosetting resin and/or the photo-curable resin, and the like may be used, but the preferred embodiment of the present invention is not particularly limited thereto. For convenience of explanation, FIG. 1 does not illustrate a detailed configuration of an inner layer circuit, but it may be sufficiently recognized by those skilled in the art that a general circuit board on which at least one layer of circuit is formed on the insulating layer may be used.

In the circuit board field, the circuit layer may be applied with any material which may be used as a conductive metal without being limited. In the printed circuit board, copper may be typically used.

As the insulating layer 102, a resin insulating layer may be used.

As a material of the resin insulating layer, a thermosetting resin such as an epoxy resin, a thermoplastic resin such as polyimide, polyethylene terephthalate (PET), or a resin, for example, a prepreg in which reinforcing materials, such as a glass fiber or an inorganic filler, are impregnated therein may be used. In addition, the thermosetting resin and/or the photo-curable resin, and the like may be used, but the preferred embodiment of the present invention is not particularly limited thereto.

Herein, the resist layer 200 may be a photosensitive resist.

As the photosensitive resist, a dry film or a positive liquid photo resist (L-LPR) may be used. A positive film and a negative film are mainly used to mold the circuit of the printed circuit board.

At the time of foil ring the opening D of the resist layer 200, the connection pad 101 formed on the insulating layer 102 is first exposed by an exposing and developing process.

Further, at least one protrusion B on an inner wall of the opening D formed by the laser machining is formed to improve a contact area with a solder ball 301 to be described below.

The structure is effective to prevent the solder ball 301 from separating and widens the contact area with the solder ball 301 to improve the adhesion.

The cross section shape of the opening D has an hourglass shape in which a first portion A which has a width of an inner diameter reduced from a lower portion of the resist layer 200 toward the protrusion B and is tapered and a second portion C which has a width of an inner diameter reduced from an upper portion of the resist layer 200 toward the protrusion B and is tapered are joined.

In this case, the protrusion B may be formed at a central portion of the resist layer 200 but is not particularly limited and therefore may be implemented to have various angles and shapes that a designer wants.

The connection pad 101 may be applied with any material which may be used as a conductive metal without being limited. In the printed circuit board, copper may be typically used. The surface treatment layer formed to protect the connection pad 101 exposed by the opening D may be a thin electroplated Ni/Au layer made of a metal composite material.

When the surface treatment layer 300 is coupled with the solder, tin (Sn) within the solder may be coupled with the surface treatment layer 300 to form the thin inter metallic compound (IMC) layer which is an inter metallic compound.

Method for Manufacturing Printed Circuit Board

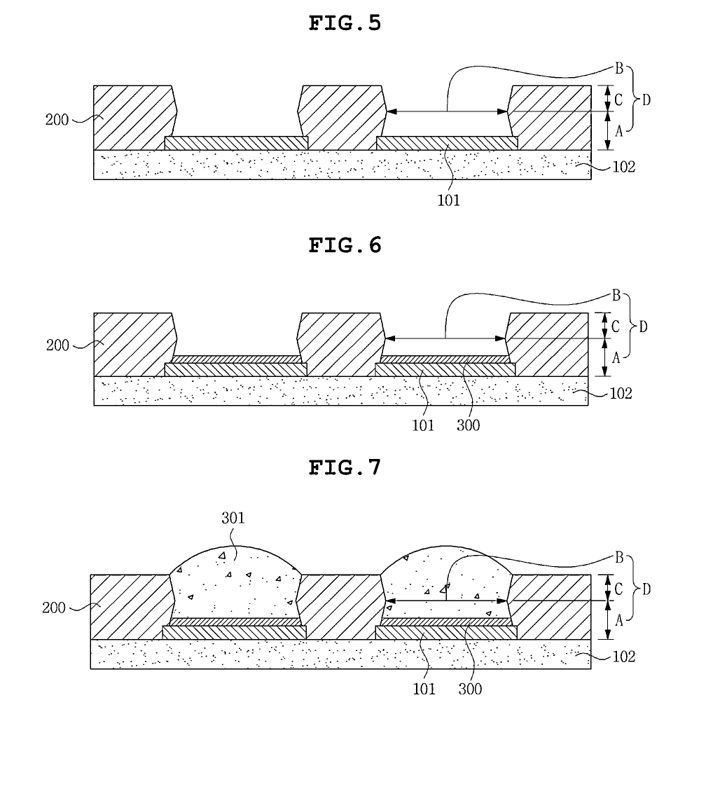

FIGS. 2 to 7 are process cross-sectional views sequentially illustrating a method for manufacturing a printed circuit board according to a preferred embodiment of the present invention.

First, referring to FIG. 2, the insulating layer 102 having the connection pad 101 is prepared.

The printed circuit board 100 may be formed of a basic member having a film shape including a resin material and materials, which is called a copper clad lamination (CCL), having patterns formed on both surfaces thereof and as the resin material which is a basic member, a thermosetting resin such as an epoxy resin, a thermoplastic resin such as polyimide, polyethylene terephthalate (PET), and a resin, for example, a prepreg, in which reinforcing materials, such as a glass fiber and an inorganic filler, are impregnated therein may be used. Further, the thermosetting resin and/or the photo-curable resin, and the like may be used, but the preferred embodiment of the present invention is not particularly limited thereto.

For convenience of explanation, FIG. 1 does not illustrate a detailed configuration of an inner layer circuit, but it may be sufficiently recognized by those skilled in the art that a general circuit board on which at least one layer of circuit is formed on the insulating layer may be used.

In the circuit board field, the circuit layer may be applied with any material which may be used as a conductive metal without being limited. In the printed circuit board, copper may be typically used.

Next, the resist layer 200 is formed on the insulating layer 102.

Herein, the resist layer 200 may be a photosensitive resist.

As the photosensitive resist, a dry film or a positive liquid photo resist (L-LPR) may be used.

A positive film and a negative film are mainly used to mold the circuit of the printed circuit board.

Next, referring to FIG. 3, the opening D is formed by removing a portion of the resist layer 200 so that the connection pad 101 is exposed.

In this case, when the exposure is made by reducing an UV light quantity, the lower surface of the resist layer 200 is maintained in a semi-cured state.

The first portion A is formed by performing the exposure and developing process.

In the first portion A, since the cross section shape of the opening D of the resist layer 200 has a shape tapered from the lower surface to the protrusion B, the diameter of the inner wall of the opening D extends toward the lower portion.

In this case, the first portion A may be exposed with predetermined light such as an X-ray, an electron beam (EB), or the like and is developed with an alkaline developer to be able to remove the non-exposed portion.

Next, referring to FIG. 4, a second portion C is formed by the laser machining.

In the second portion C, since the cross section shape of the opening D of the resist layer 200 has a shape tapered from the upper surface to the protrusion B, the diameter of the inner wall of the opening D extends toward the upper surface.

The laser machining may mainly use a CO2 laser, but may be performed by at least one kind of carbon dioxide (CO2), YAG, and excimer and in the preferred embodiment of the present invention, the kind of laser is not limited.

Next, referring to FIG. 5, the resist layer 200 of the lower portion which is in the semi-cured state is hardened.

In this case, the cross section shape of the opening D which is fully hardened by thermal hardening and then is formed in the resist layer 200 has an hourglass shape in which the first portion A which has the width of the inner diameter reduced from a lower portion of the resist layer 200 toward the protrusion B and is tapered and the second tapered portion C which has the width of the inner diameter reduced from the upper portion of the resist layer 200 toward the protrusion B and is tapered are joined.

In this case, the protrusion B may be formed at a central portion of the resist layer 200 but is not particularly limited and therefore may be implemented to have various angles and shapes that a designer wants.

Next, referring to FIG. 6, the surface treatment layer 300 is formed on the connection pad 101 exposed by the opening D of the resist layer 200.

Herein, the connection pad 101 may be applied with any material which may be used as a conductive metal without being limited. In the printed circuit board, copper may be typically used.

The surface treatment layer 300 formed to protect the connection pad 101 exposed by the opening D may be the thin electroplated Ni/Au layer made of a metal composite material.

Next, referring to FIG. 7, the solder ball 301 is attached on the surface treatment layer 300 protecting the connection pad 101.

In this case, the solder may consist of at least one selected from Pb, Sn, Ag, Cu, Au, Bi, Sb, Zn, Ni, Zr, and Mg.

When the surface treatment layer 300 is coupled with the solder, tin (Sn) within the solder is coupled with the surface treatment layer 300 to form the thin inter metallic compound (IMC) layer which is an inter metallic compound.

The IMC layer has weak brittleness and therefore when the solder ball 301 is separated, a structure and a method for relieving weak physical properties are required.

Therefore, when a stress concentration portion is formed as the protrusion B which is spaced from the IMC layer as in the preferred embodiment of the present invention, it is possible to prevent cracks from being generated on the IMC layer.

According to the preferred embodiments of the present invention, the printed circuit board and the method for manufacturing a printed circuit board may be applied to various products requiring the solder bonding technology, thereby manufacturing the product having high utilization, low defective rate, and high reliability.

Although the embodiments of the present invention have been disclosed for illustrative purposes, it will be appreciated that the present invention is not limited thereto, and those skilled in the art will appreciate that various modifications, additions, and substitutions are possible, without departing from the scope and spirit of the invention.

Accordingly, any and all modifications, variations, or equivalent arrangements should be considered to be within the scope of the invention, and the detailed scope of the invention will be disclosed by the accompanying claims.

What is claimed is:

1. A printed circuit board, comprising:
an insulating layer having a connection pad; and
a resist layer formed on the insulating layer and provided with an opening so that the connection pad is exposed,
wherein a wall surface of an opening of the resist layer has at least one protrusion.

2. The printed circuit board as set forth in claim 1, wherein a cross section shape of the opening of the resist layer has an hourglass shape which the opening is converged at the protrusion between an upper surface and a lower surface of the resist layer.

3. The printed circuit board as set forth in claim 1, wherein the opening includes a first portion which is tapered toward the protrusion and the lower surface and a second portion which is tapered toward the protrusion and the upper surface.

4. The printed circuit board as set forth in claim 1, further comprising:
a solder ball attached on the connection pad.

5. The printed circuit board as set forth in claim 4, further comprising:
a surface treatment layer between the connection pad and the solder ball.

6. A method for manufacturing a printed circuit board, comprising:
preparing an insulating layer having a connection pad; and
forming a resist layer having on opening on the insulating layer so that the connection pad is exposed,
wherein a wall surface of the opening of the resist layer has at least one protrusion.

7. The method as set forth in claim 6, wherein a cross section shape of the opening of the resist layer has an hourglass shape which the opening is converged at the protrusion between an upper surface and a lower surface of the resist layer.

8. The method as set forth in claim 7, wherein the opening includes a first portion which is tapered toward the protrusion and the lower surface and a second portion which is tapered toward the protrusion and the upper surface.

9. The method as set forth in claim 8, wherein the first portion is formed by exposing and developing.

10. The method as set forth in claim 8, wherein the second portion is formed by laser machining.

11. The method as set forth in claim 6, further comprising:
forming a solder ball attached on the connection pad.

12. The method as set forth in claim 6, further comprising:
forming a surface treatment layer on the connection pad.
